(19) United States
(12) Patent Application Publication
(10) Pub. No.: US 2024/0290760 A1
(43) Pub. Date: Aug. 29, 2024

(54) DISPLAY DEVICE

(71) Applicant: LG Display Co., Ltd., Seoul (KR)

(72) Inventors: WonJun CHOI, Paju-si (KR); ChangBae PARK, Goyang-si (KR)

(73) Assignee: LG Display Co., Ltd., Seoul (KR)

(21) Appl. No.: 18/589,114

(22) Filed: Feb. 27, 2024

(30) Foreign Application Priority Data
Feb. 28, 2023 (KR) 10-2023-0027189

(51) Int. Cl. H01L 25/075; H01L 27/12; H01L 33/60

(52) U.S. Cl. CPC H01L 25/0753; H01L 27/1222; H01L 33/60

(57) ABSTRACT

Discussed is a display device that can include a substrate including an active area and a non-active area adjacent to the active area, the active area including plurality of sub pixels of at least one pixel, a plurality of light emitting diodes disposed in the plurality of sub pixels, respectively, and including a first electrode and a second electrode, respectively, a plurality of transistors disposed in the plurality of sub pixels, respectively, a plurality of reflection plates disposed below the plurality of light emitting diodes in the plurality of sub pixels, respectively, an insulating layer disposed on the plurality of reflection plates. The plurality of reflection plates respectively include a first part overlapping a contact hole of the insulating layer and a second part extending from the first part, and the first part and the second part include different materials from each other.

### CROSS-REFERENCE TO RELATED APPLICATION

This application claims priority of Korean Patent Application No. 10-2023-0027189 filed on Feb. 28, 2023, in the Korean Intellectual Property Office, the entire contents of which is hereby expressly incorporated by reference into the present application.

### BACKGROUND OF THE DISCLOSURE

### Field

The present disclosure relates to a display device, and more particularly, to a display device using a light emitting diode (LED).

### Discussion of the Related Art

Display devices can be used for various purposes, such as a monitor of a computer, a television, a cellular phone, or the like. Such display devices can include an organic light emitting display (OLED) device which is a self-emitting device, a liquid crystal display (LCD) device which requires a separate light source, and other types of devices.

Recently, there has been efforts to develop a display device with a large display area, a reduced volume and reduced weight. Such a display device can be used for personal digital assistants as well as monitors of computers and televisions more effectively.

In this light, a display device including a light emitting diode (LED) is attracting attention as a next generation display device. Since the LED is formed of an inorganic material, rather than an organic material, reliability can be improved so that a lifespan of the display device including the LED can be longer than that of the liquid crystal display device or the organic light emitting display device. Further, the LED has a fast operating speed, improved luminous efficiency, and a stronger impact resistance than the organic light emitting display device so that a stability is improved and an image having a higher luminance can be displayed.

### SUMMARY OF THE DISCLOSURE

An object to be achieved by the present disclosure is to provide a display device including a reflection plate which satisfies both an optical characteristic and an electrical characteristic.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device includes a substrate including an active area in which a plurality of sub pixels are disposed and a non-active area enclosing the active area. The display device further includes a plurality of light emitting diodes which are disposed in each of the plurality of sub pixels and includes a first electrode and a second electrode. The display device further includes a plurality of transistors disposed in each of the plurality of sub pixels. The display device further includes a plurality of reflection plates which are disposed below the plurality of light emitting diodes in the plurality of sub pixels. The display device further includes an insulating layer disposed on the plurality of reflection plates. The plurality of reflection plates include a first part overlapping a contact hole of the insulating layer and a second part extending from the first part, and the first part and the second part are formed of different materials from each other.

Other detailed matters of the example embodiments are included in the detailed description and the drawings.

According to the present disclosure, even though a material having a high reflectance is used for the reflection plate, formation of an oxide film of the reflection plate is suppressed to suppress the increase in a resistance of the reflection plate.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an example embodiment of the present disclosure;

FIG. 2A is a partial cross-sectional view of a display device according to an example embodiment of the present disclosure;

FIG. 2B is a perspective view of a tiling display device according to an example embodiment of the present disclosure;

FIG. 3 is a plan view of a display panel of a display device according to an example embodiment of the present disclosure;

FIG. 4 is a plan view of a pixel area of a display device according to an example embodiment of the present disclosure;

FIGS. 5A and 5B are plan views of a reflection plate in a pixel area of a display device according to an example embodiment of the present disclosure;

FIGS. 6A to 6D are cross-sectional views of a display device according to an example embodiment of the present disclosure; and

FIG. 7 is a cross-sectional view of a pad area of a display device according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All components of each display device according to all embodiments of the present disclosure are operatively coupled and configured.

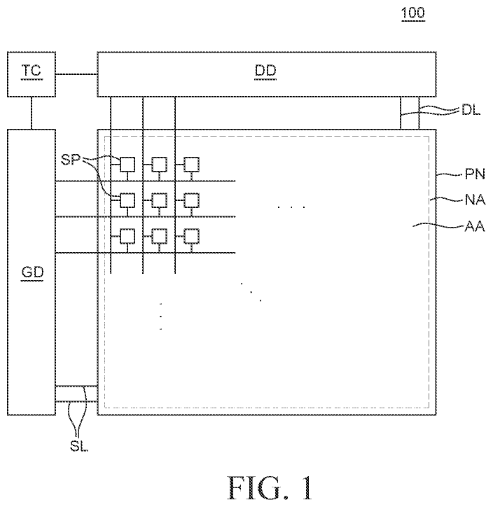

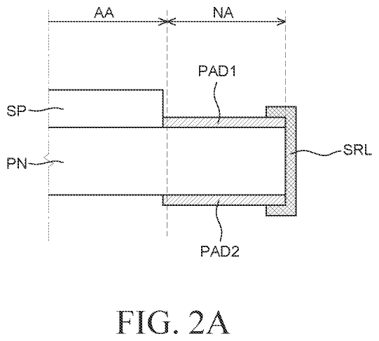

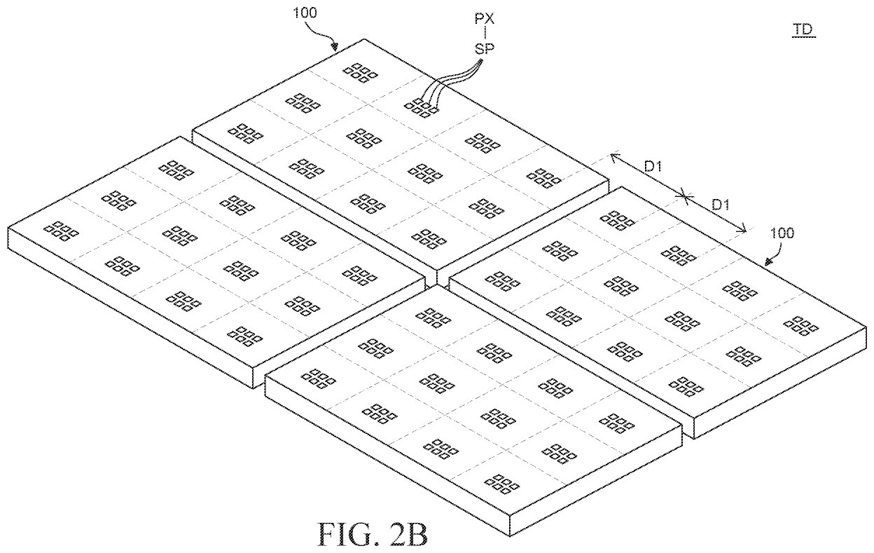

FIG. 1 is a schematic diagram of a display device according to an example embodiment of the present disclosure. FIG. 2A is a partial cross-sectional view of a display device according to an example embodiment of the present disclosure. FIG. 2B is a perspective view of a tiling display device according to an example embodiment of the present disclosure. In FIG. 1, for the convenience of description, among various components of the display device, only a display panel PN, a gate driver GD, a data driver DD, and a timing controller TC are illustrated.

Referring to FIG. 1, the display device includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD can supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, each of the plurality of sub pixels SP can be connected to a high potential power line, a low potential power line, a reference line, and the like.

In the display panel PN, an active area AA and the non-active area NA enclosing the active area AA can be defined.

The active area AA is an area where images are displayed in the display device. In the active area AA, a plurality of sub pixels SP which configures a plurality of pixels PX and a circuit for driving the plurality of sub pixels SP can be disposed. The plurality of sub pixels SP are a minimum unit which configures the active area AA and n sub pixels SP can form one pixel PX. In each of the plurality of sub pixels SP, a light emitting diode 130 and a thin film transistor for driving the light emitting diode 130 can be disposed. The plurality of light emitting diodes 130 can be defined in different ways depending on the type of the display panel PN. For example, when the display panel PN is an inorganic light emitting display panel, the light emitting diode 130 can be a light emitting diode (LED) or a micro light emitting diode (LED).

In the active area AA, a plurality of wiring lines which transmit various signals to the plurality of sub pixels SP are disposed. For example, the plurality of wiring lines can include a plurality of data lines DL which supply a data voltage to each of the plurality of sub pixels SP, a plurality of scan lines SL which supply a scan signal to each of the plurality of sub pixels SP, and the like. The plurality of scan lines SL extend in one direction in the active area AA to be connected to the plurality of sub pixels SP and the plurality of data lines DL extend in a direction different from the one direction in the active area AA to be connected to the plurality of sub pixels SP. In addition, in the active area AA, a low potential power line, a high potential power line, and the like can be further disposed, but are not limited thereto.

The non-active area NA is an area where images are not displayed so that the non-active area NA can be defined as an area extending from the active area AA. In the non-active area NA, a link line which transmits a signal to the sub pixel SP of the active area AA, a pad electrode, a driving IC, such as a gate driver IC or a data driver IC, or the like, can be disposed.

In the meantime, the non-active area NA can be located on a rear surface of the display panel PN, that is, a surface on which the sub pixels SP are not disposed or can be omitted, and is not limited as illustrated in the drawing.

In the meantime, a driver, such as a gate driver GD, a data driver DD, and a timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner. For example, the data driver DD and the timing controller TC are disposed in separate flexible film and printed circuit board. The data driver DD and the timing controller TC can be electrically connected to the display panel PN by bonding the flexible film and the printed circuit board to the pad electrode disposed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel can be increased.

In contrast, when the gate driver GD is mounted in the active area AA in the GIA manner and a side line SRL which connects the signal line on the front surface of the display panel PN to the pad electrode on a rear surface of the display panel PN is disposed to bond the flexible film and the printed circuit board onto a rear surface of the display panel PN, the non-active area NA can be minimized on the front surface of the display panel PN. That is, when the gate driver GD, the data driver DD, and the timing controller TC are connected to the display panel PN as described above, a zero bezel with substantially no bezel can be implemented.

Specifically, referring to FIGS. 2A and 2B, in the non-active area NA of the display panel PN, a plurality of pad electrodes for transmitting various signals to the plurality of sub pixels SP are disposed. For example, in the non-active area NA on the front surface of the display panel PN, a plurality of first pad electrodes PAD1 which transmit a signal to the plurality of sub pixels SP are disposed. In the non-active area NA on the rear surface of the display panel PN, a plurality of second pad electrode PAD2 which are electrically connected to a driving component, such as a flexible film and the printed circuit board, is disposed. That is, on the front surface of the display panel PN on which images are displayed, only a pad area of the non-active area NA in which the first pad electrode PAD1 is disposed can be formed at minimum.

In this case, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL can electrically connect a first pad electrode PAD1 on the front surface of the display panel PN and a second pad electrode PAD2 on the rear surface of the display panel PN. Therefore, a signal from a driving component on the rear surface of the display panel PN can be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize an area of the non-active area NA on the front surface of the display panel PN.

Referring to FIG. 2B, a tiling display device TD having a large screen size can be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality can be improved.

For example, the plurality of sub pixels SP can form one pixel PX and a distance D1 between an outermost pixel PX of one display device 100 and an outermost pixel PX of another display device 100 adjacent to one display device can be implemented to be equal to a distance D1 between pixels PX in one display device 100. Accordingly, a constant distance D1 between pixels PX between the display devices 100 is configured to minimize the seam area.

However, FIGS. 2A and 2B are illustrative so that the display device 100 according to the example embodiment of the present disclosure can be a general display device with a bezel, but is not limited thereto.

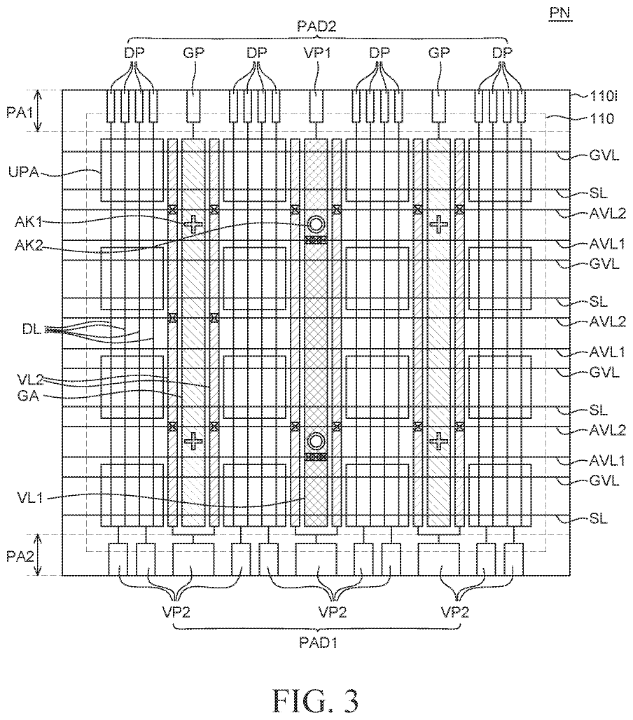

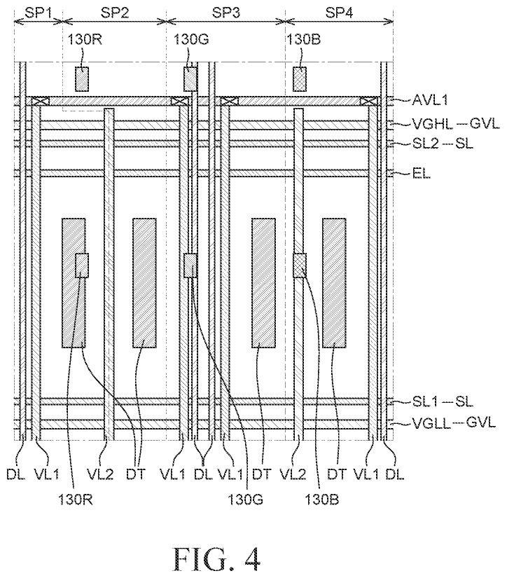

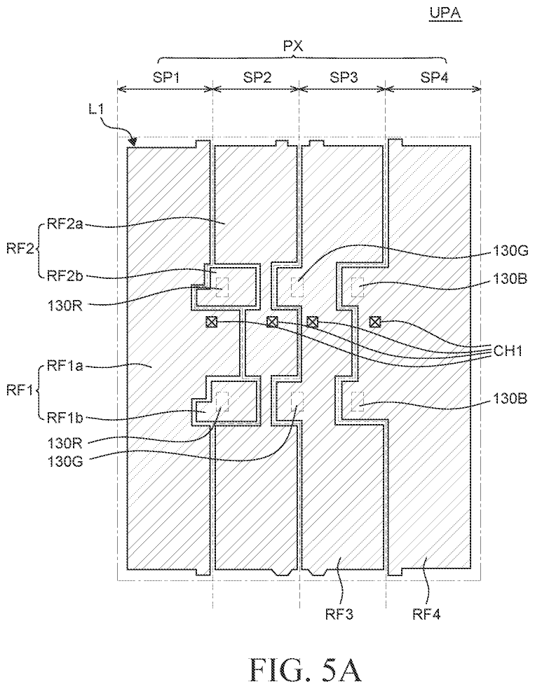

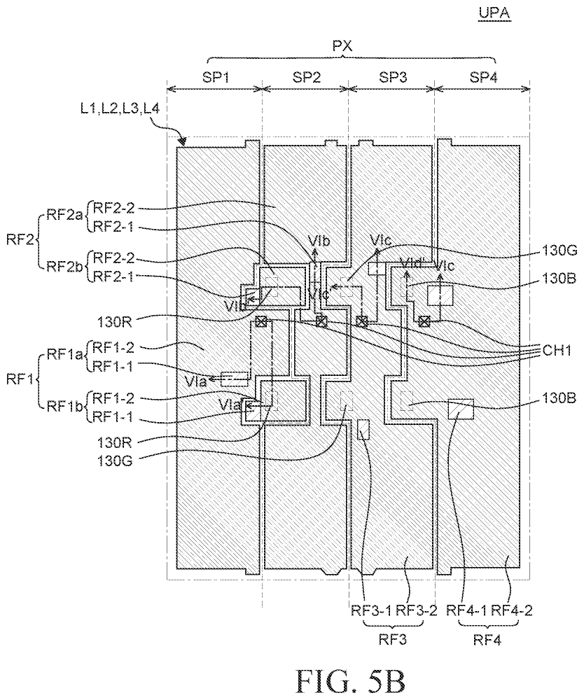

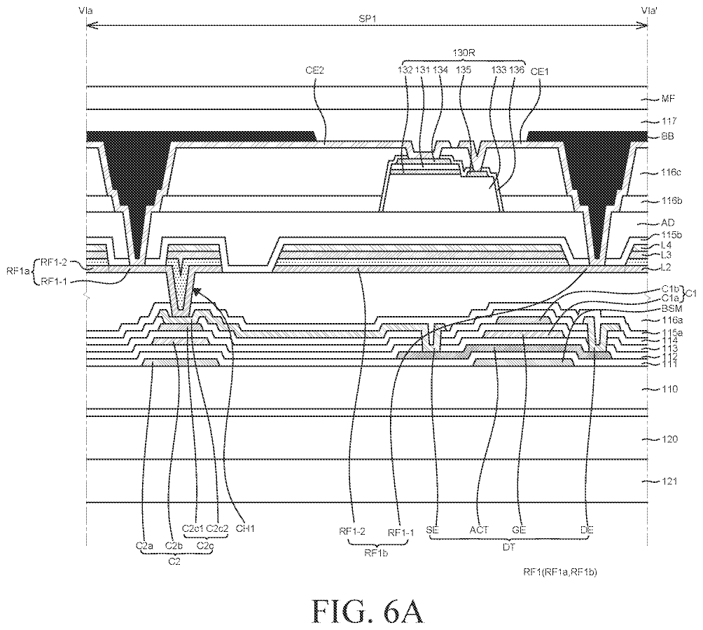

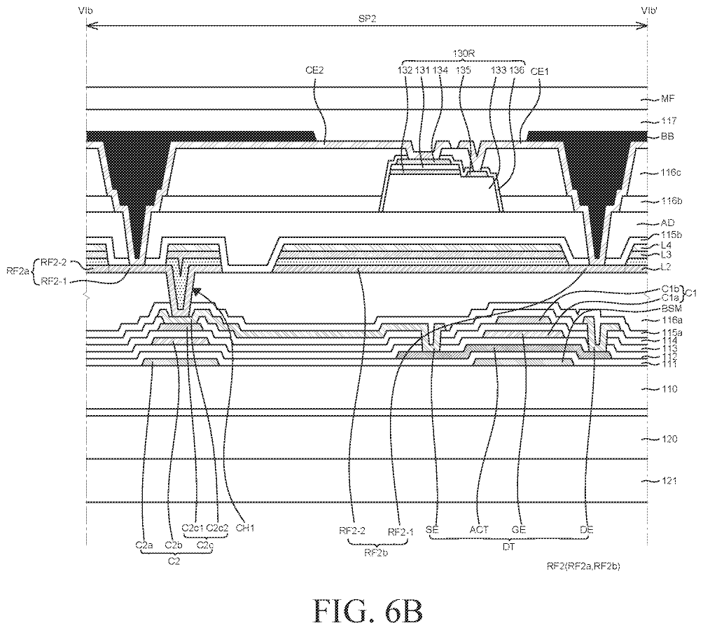

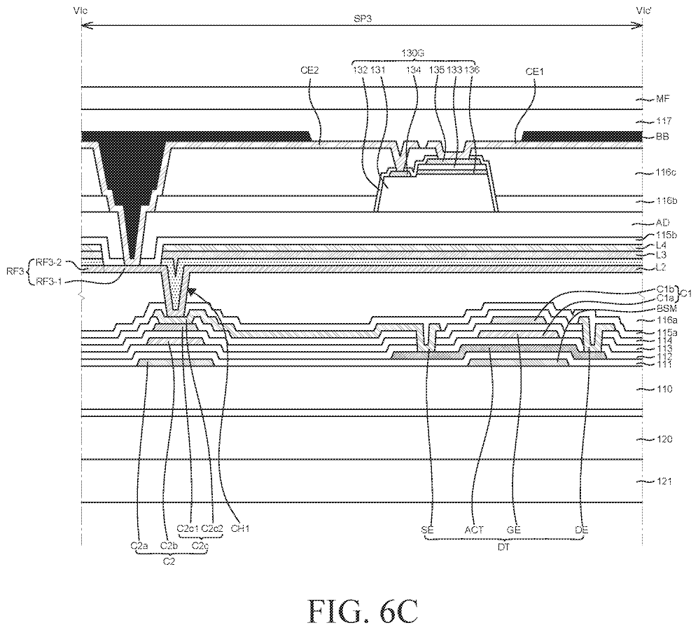

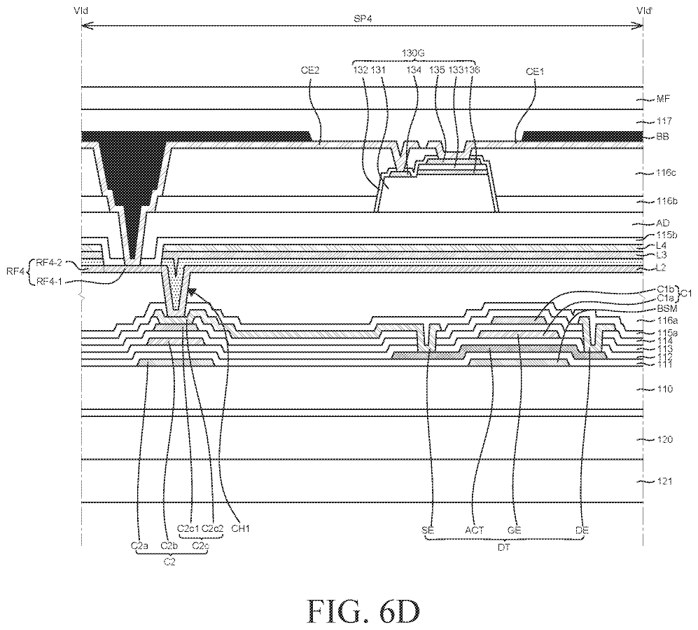

FIG. 3 is a plan view of a display panel of a display device according to an example embodiment of the present disclosure. FIG. 4 is a plan view of a pixel area of a display device according to an example embodiment of the present disclosure. FIGS. 5A and 5B are plan views of a reflection plate in a pixel area of a display device according to an example embodiment of the present disclosure. FIG. 5A is a plan view of a first layer of a reflection plate. FIG. 5B is a plan view of a plurality of layers of a reflection plate. FIGS. 6A to 6D are cross-sectional views of a display device according to an example embodiment of the present disclosure. For the convenience of description, in FIG. 4, only a plurality of light emitting diodes 130, a driving transistor DT of the pixel circuit, and a plurality of wiring lines are illustrated and in FIGS. 5A and 5B, only a plurality of light emitting diodes 130 are illustrated by a dotted line. FIG. 6A is a cross-sectional view taken along the line VIa-VIa′ of FIG. 5B. FIG. 6B is a cross-sectional view taken along VIb-VIb′ of FIG. 5B. FIG. 6C is a cross-sectional view taken along VIc-VIc′ of FIG. 5B. FIG. 6D is a cross-sectional view taken along the line VId-VId′ of FIG. 5B. FIG. 6A is a cross-sectional view for a first sub pixel, FIG. 6B is a cross-sectional view for a second sub pixel, FIG. 6C is a cross-sectional view for a third sub pixel, and FIG. 6D is a cross-sectional view for a fourth sub pixel.

First, referring to FIGS. 3 to 6D, the display panel PN includes a first substrate 110. The first substrate 110 is a substrate which supports components disposed above the display device 100 and can be an insulating substrate. A plurality of pixels PX are disposed on the first substrate 110 to display images. For example, the first substrate 110 can be formed of glass, resin, or the like. Further, the first substrate 110 can include polymer or plastic. In some example embodiments, the first substrate 110 can be formed of a plastic material having flexibility.

Referring to FIG. 3, in the first substrate 110, a plurality of pixel areas UPA, a plurality of gate driving areas GA, and a plurality of pad areas are disposed. Among them, the plurality of pixel areas UPA and the plurality of gate driving areas GA can be included in the active area AA of the display panel PN.

First, the plurality of pixel areas UPA are areas in which the plurality of pixels PX are disposed. The plurality of pixel areas UPA can be disposed by forming a plurality of rows and a plurality of columns. Each of the plurality of pixels PX disposed in the plurality of pixel areas UPA includes a plurality of sub pixels SP. Each of the plurality of sub pixels SP includes a light emitting diode 130 and a pixel circuit to independently emit light.

The plurality of gate driving areas GA are areas where gate drivers GD are disposed. The gate driver GD can be mounted in the active area AA in a gate in active area (GIA) manner. For example, the gate driving area GA can be disposed along a row direction and/or column direction between the plurality of pixel areas UPA. The gate driver GD disposed in the gate driving area GA can supply the scan signal to the plurality of scan lines SL.

The gate driver GD disposed in the gate driving area GA can include a circuit for outputting a scan signal. At this time, the gate driver GD can include, for example, a plurality of transistors and/or capacitors. Here, active layers of the plurality of transistors can be formed of a semiconductor material, such as an oxide semiconductor, amorphous silicon, or polysilicon, but are not limited thereto. The active layers of the plurality of transistors can be formed of the same material or different materials from each other. Further, the active layers of the plurality of transistors of the gate driver can be formed of the same material as active layers of various transistors of the pixel circuit or formed of different materials from each other.

The plurality of pad areas are areas in which a plurality of first pad electrodes PAD1 are disposed. The plurality of first pad electrodes PAD1 can transmit various signals to various wiring lines extending in a column direction in the active area AA. For example, the plurality of first pad electrodes PAD1 include a data pad DP, a gate pad GP, a high potential power pad VP1, and a low potential power pad VP2. The data pad DP transmits a data voltage to the data line DL and the gate pad GP transmits a clock signal, a start signal, a gate low voltage, and a gate high voltage for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas includes a first pad area PA1 located at an upper edge of the display panel PN and a second pad area PA2 of the display panel PN. At this time, in the first pad area PA1 and the second pad area PA2, different types of first pad electrodes PAD1 can be disposed. For example, in the first pad area PA1, among the plurality of first pad electrodes PAD1, the data pad DP, the gate pad GP, and the high potential power pad VP1 can be disposed and in the second pad area PA2, the low potential power pad VP2 can be disposed.

At this time, the plurality of first pad electrodes PAD1 can be disposed to have different sizes, respectively. For example, the plurality of data pads DP which is connected to the plurality of data lines DL one to one can have a narrower width and the high potential power pad VP1, the low potential power pad VP2, and the gate pad GP can have a larger width. However, widths of the data pad DP, the gate pad GP, the high potential power pad VP1, and the low potential power pad VP2 illustrated in FIG. 3 are illustrative so that the first pad electrode PAD1 can be configured in various sizes, but is not limited thereto.

In the meantime, in order to reduce the bezel of the display panel PN, an edge of the display panel PN can be cut to be removed. The plurality of pixels PX, the plurality of wiring lines, and the plurality of first pad electrodes PAD1 are disposed on an initial first substrate 110i and an edge part of the initial first substrate 110i is ground to reduce the bezel area. During the grinding process, a part of the initial first substrate 110i is removed to form a first substrate 110 with a smaller size. At this time, parts of the plurality of first pad electrodes PAD1 and wiring lines disposed at the edge of the first substrate 110 can be removed. Accordingly, only a part of the plurality of first pad electrodes PAD1 can remain on the first substrate 110.

Next, the plurality of data lines DL which extends in a column direction from the plurality of first pad electrodes PAD1 is disposed on the first substrate 110 of the display panel PN. The plurality of data lines DL can extend from the plurality of data pads DP of the first pad area PA1 toward the plurality of pixel areas UPA. The plurality of data lines DL can extend in a column direction and can be disposed to overlap the plurality of pixel areas UPA. Therefore, the plurality of data lines DL can transmit the data voltage to the pixel circuit of each of the plurality of sub pixels SP.

The plurality of high potential power lines VL1 extending in the column direction is disposed on the first substrate 110 of the display panel PN. Some of the plurality of high potential power lines VL1 extend from the high potential power pad VP1 of the first pad area PA1 to the plurality of pixel areas UPA to transmit the high potential power voltage to the light emitting diode 130 of each of the plurality of sub pixels SP. The others of the plurality of high potential power lines VL1 can be electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 can be disposed.

The plurality of low potential power lines VL2 extending in the column direction is disposed on the first substrate 110 of the display panel PN. At least some of the plurality of low potential power lines VL2 extend from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 can be electrically connected to the other low potential power line VL2 by means of an auxiliary low potential power line AVL2 to be described below.

The plurality of scan lines SL extending in the row direction is disposed on the first substrate 110 of the display panel PN. The plurality of scan lines SL extends in the row direction and can be disposed across the plurality of pixel areas UPA and the plurality of gate driving areas GA. The plurality of scan lines SL can transmit the scan signal from the gate driver GD to the pixel circuits of the plurality of sub pixels SP.

A plurality of auxiliary high potential power lines AVL1 extending in the row direction is disposed on the first substrate 110 of the display panel PN. The plurality of auxiliary high potential power lines AVL1 can be disposed in an area between the plurality of pixel areas UPA. The plurality of auxiliary high potential power lines AVL1 extending in the row direction is electrically connected to the plurality of high potential power lines VL1 extending in the column direction through a contact hole and can form a mesh structure. Therefore, the plurality of auxiliary high potential power lines AVL1 and the plurality of high potential power lines VL1 are configured to form a mesh structure to minimize voltage drop and voltage deviation.

A plurality of auxiliary low potential power lines AVL2 extending in the row direction is disposed on the first substrate 110 of the display panel PN. The plurality of auxiliary low potential power lines AVL2 can be disposed in an area between the plurality of pixel areas UPA. The plurality of auxiliary low potential power lines AVL2 extending in the row direction is electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize voltage deviation.

Referring to FIGS. 3 and 4, the plurality of gate driving lines GVL extending in the row direction and the column direction is disposed on the first substrate 110 of the display panel PN. Some of the plurality of gate driving lines GVL extend from the gate pad GP of the first pad area PA1 to the gate driving area GA to transmit a signal to the gate driver GD. The others of the plurality of gate driving lines GVL can extend in the row direction and transmit the signal to the gate drivers GD of the plurality of gate driving areas GA. Therefore, various signals are transmitted from the gate driving line GVL to the gate driver GD to drive the gate driver GD.

The plurality of gate driving lines GVL can include wiring lines which transmit a clock signal, a start signal, a gate high voltage, a gate low voltage, and the like to the gate driver GD. Therefore, various signals are transmitted from the gate driving line GVL to the gate driver GD to drive the gate driver GD.

For example, referring to FIG. 4, the plurality of gate driving lines GVL can include a gate power line which transmits a power voltage to the gate driver GD of the gate driving area GA. The plurality of gate power lines includes a first gate power line VGHL which transmits a gate high voltage to the gate driver GD and a second gate power line VGLL which transmits a gate low voltage to the gate driver GD.

A plurality of alignment keys AK1 and AK2 are disposed in an area between the plurality of pixel areas UPA in the display panel PN. The plurality of alignment keys AK1 and AK2 is used for alignment during the manufacturing process of the display panel PN. The plurality of alignment keys AK1 and AK2 includes a first alignment key AK1 and a second alignment key AK2.

The first alignment key AK1 can be disposed in the gate driving area GA between the plurality of pixel areas UPA. The first alignment key AK1 can be used to inspect an alignment position of the plurality of light emitting diodes 130. For example, the first alignment key AK1 can have a cross shape, but is not limited thereto.

The second alignment key AK2 can be disposed to overlap the high potential power line VL1 between the plurality of pixel areas UPA. In the high potential power line VL1, a hole overlapping the second alignment key AK2 is formed to divide the second alignment key AK2 and the high potential power line VL1. The second alignment key AK2 can be used to align the display panel PN and a donor. The display panel PN and the donor can be aligned using the second alignment key AK2 and the plurality of light emitting diodes 130 of the donor can be transferred onto the display panel PN. For example, the second alignment key AK2 can have a circular ring shape, but is not limited thereto.

Hereinafter, the plurality of sub pixels SP of the pixel area UPA will be described in more detail with reference to FIGS. 4 to 6D.

Referring to FIGS. 4 to 5B, in one pixel area UPA, a plurality of sub pixels SP which forms one pixel PX are disposed. For example, the plurality of sub pixels SP can include a first sub pixel SP1, a second sub pixel SP2, a third sub pixel SP3, and a fourth sub pixel SP4 which emit different color light. Red light emitting diodes 130R can be disposed in the first sub pixel SP1 and the second sub pixel SP2, a green light emitting diode 130G can be disposed in the third sub pixel SP3, and a blue light emitting diode 130B can be disposed in the fourth sub pixel SP4. The first sub pixel SP1 and the second sub pixel SP2 which emit the same color light can include the red light emitting diodes 130R and the pixel circuits, respectively, to independently emit light, but are not limited thereto.

Referring to FIG. 4, as described above, a plurality of wiring lines which supply various signals to the plurality of sub pixels SP is disposed in the plurality of pixel areas UPA of the first substrate 110. For example, the plurality of data lines DL, the plurality of high potential power lines VL1, and the plurality of low potential power lines VL2 extending in the column direction can be disposed on the first substrate 110. For example, the plurality of emission control signal lines, the plurality of auxiliary high potential power lines AVL1, the plurality of auxiliary low potential power lines AVL2, the plurality of first scan lines SL1, and the plurality of second scan lines SL2 extending in the row direction can be disposed on the first substrate 110. The high potential power line VL1 extending in the column direction can be electrically connected to the auxiliary high potential power line AVL1 extending in the row direction through a contact hole. At this time, the emission control signal line transmits an emission control signal to the pixel circuits of the plurality of sub pixels SP to control emission timing of each of the plurality of sub pixels SP.

Some gate driving lines GVL which transmit a signal to each of the plurality of gate drivers GD disposed to be spaced apart from each other with the pixel area UPA therebetween can be disposed across the pixel area UPA while extending to the row direction. For example, a first gate power line VGHL which supplies a gate high voltage to the gate driver GD and a second gate power line VGLL which supplies a gate low voltage can be disposed across the pixel area UPA.

In the meantime, even though it is illustrated that the plurality of scan lines includes a first scan line SL1 and a second scan line SL2, the configuration of the plurality of scan lines can vary depending on the pixel circuit configuration of the sub pixel SP, but is not limited thereto.

Referring to FIGS. 5A and 5B, a plurality of reflection plates are disposed in the pixel area UPA. The plurality of reflection plates reflects the light emitted from the light emitting diode 130 and can be also used as an electrode which electrically connects the light emitting diode 130 and the pixel circuit.

Referring to FIG. 5A, first layers L1 of the plurality of reflection plates are disposed. The first layer L1 can be disposed to have shapes corresponding to the plurality of sub pixels SP, respectively, in the pixel area UPA. At this time, the first layers L1 can be disposed to be spaced apart from each other between the plurality of sub pixels SP. Therefore, that is, the first layers L1 can configure a first reflection plate RF1, a second reflection plate RF2, a third reflection plate RF3, and a fourth reflection plate RF4 which are disposed to be spaced apart from each other at boundaries of the first sub pixel SP1, the second sub pixel SP2, the third sub pixel SP3, and the fourth sub pixel SP4.

In the meantime, the first layer L1 can be disposed to be spaced apart from each other between the 1-2-th reflection plate RF1b and the 1-1-th reflection plate RF1a disposed in an area overlapping the red light emitting diode 130R in the first sub pixel SP1. Further, the first layer L1 can be disposed to be spaced apart from each other between the 2-2-th reflection plate RF2b and the 2-1-th reflection plate RF2a disposed in an area overlapping the red light emitting diode 130R in the second sub pixel SP2.

Referring to FIG. 5B, the plurality of reflection plates can include a second layer L2, a third layer L3, and a fourth layer L4 disposed on the first layer L1 in each sub pixel SP. The second layer L2, the third layer L3, and the fourth layer L4 can be disposed so as to overlap a partial area of the first layer L1. Therefore, a reflection plate which is configured only by the first layer L1, among the plurality of reflection plates, can be referred to as a first part and a reflection plate which is configured by a plurality of layers L1, L2, L3, and L4 including the first layer L1 can be referred to as a second part. However, the embodiments of the disclosure are not limited thereto. For example, the second part of the reflection plate need not have four layers, but can have another number of layers, which can be greater than four or less than four. Also, the first part of the reflection plate can have more than two layers. Although the first part is discussed as having less number of layers than that of the second part, the embodiments of the disclosure are not limited thereto. In other embodiments, the number of layers can be the same in the first part and the second part. Also, the layers L1, L2, L3, and L4 can have the same shape or different shapes from each other.

For example, referring to FIG. 5B, the 1-1-th reflection plate RF1a can include a first part RF1-1 configured by the first layer L1 and a second part RF1-2 which extends from the first part RF1-1 and is formed of a material different from that of the first part RF1-1. The 1-2-th reflection plate RF1b can include a first part RF2-1 configured by the first layer L1 and a second part RF1-2 which extends from the first part RF1-1 and is formed of a material different from that of the first part RF1-1. The 2-1-th reflection plate RF2a can include a first part RF2-1 configured by the first layer L1 and a second part RF2-2 which extends from the first part RF2-1 and is formed of a material different from that of the first part RF2-1. The 2-2-th reflection plate RF2b can include a first part RF2-1 configured by the first layer L1 and a second part RF2-2 which extends from the first part RF2-1 and is formed of a material different from that of the first part RF2-1. The third reflection plate RF3 can include a first part RF3-1 configured by the first layer L1 and a second part RF3-2 which extends from the first part RF3-1 and is formed of a material different from that of the first part RF3-1. The fourth reflection plate RF4 can include a first part RF4-1 configured by the first layer L1 and a second part RF4-2 which extends from the first part RF4-1 and is formed of a material different from that of the first part RF4-1.

The first part RF1-1 of the 1-1-th reflection plate RF1a, the first part RF1-1 of the 1-2-th reflection plate RF1b, the first part RF2-1 of the 2-1-th reflection plate RF2a, the first part RF2-1 of the 2-2-th reflection plate RF2b, the first part RF3-1 of the third reflection plate RF3, and the first part RF4-1 of the fourth reflection plate RF4 are disposed in an area of the reflection plate overlapping a contact hole which is connected to the light emitting diode 130 to be used as electrodes which electrically connect the light emitting diode 130 and the pixel circuit.

The second part RF1-2 of the 1-1-th reflection plate RF1a, the second part RF1-2 of the 1-2-th reflection plate RF1b, the second part RF2-2 of the 2-1-th reflection plate RF2a, the second part RF2-2 of the 2-2-th reflection plate RF2b, the second part RF3-2 of the third reflection plate RF3, and the second part RF4-2 of the fourth reflection plate RF4 can also be disposed in an area overlapping the light emitting diode 130 as illustrated in FIG. 5B, but the present disclosure is not limited thereto. The plurality of reflection plates will be described in more detail below with reference to FIGS. 6A to 6D.

The pixel circuit for driving the light emitting diode 130 is disposed in each of the plurality of sub pixels SP on the first substrate 110. The pixel circuit can include a plurality of thin film transistors and a plurality of capacitors. In FIGS. 4, for the convenience of description, only a driving transistor DT, a first capacitor C1, and a second capacitor, among configurations of the pixel circuit are illustrated. However, the pixel circuit can further include a switching transistor, a sensing transistor, an emission control transistor, and the like, but is not limited thereto.

In FIG. 5B, a shape outline of the plurality of reflection plates RF1, RF2, RF3 and RF4 corresponding to the plurality of sub pixels SP1, SP2, SP3 and SP4 are shown as substantially rectangular with some irregular protrusions and/or recesses. However, embodiments of the disclosure are not limited thereto, and the shape outlines of one or more of the plurality of reflection plates RF1, RF2, RF3 and RF4 can be other shapes, including oval, polygonal, semicircular, and others. Also, each of the plurality of reflection plates RF1, RF2, RF3 and RF4 can have additional plates. For example, the first reflection plate RF1 is shown having the 1-1-th reflection plate RF1a and the 1-2-th reflection plate RF1b, but embodiments of the present disclosure are not limited thereto. For example, the first reflection plate RF1 can have additional reflection plates. Similarly, reflection plates RF2, RF3 and RF4 can also include additional reflection plates. The additional reflection plates can have any number of the layers L1, L2, L3, and L4, or additional layers. Further, additional reflection plates for each of the plurality of reflection plates RF1, RF2, RF3 and RF4 can have the same or different shapes.

Referring to FIGS. 6A to 6D, a light shielding layer BSM is disposed on the first substrate 110. The light shielding layer BSM blocks light which is incident to an active layer ACT of the plurality of transistors to minimize a leakage current. For example, the light shielding layer BSM is disposed below the active layer ACT of the driving transistor DT to block light incident onto the active layer ACT. If light is irradiated onto the active layer ACT, a leakage current is generated, which deteriorates the reliability of the transistor. Accordingly, the light shielding layer BSM which blocks the light is disposed on the first substrate 110 to improve the reliability of the driving transistor DT. The light shielding layer BSM can be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the light shielding layer BSM. The buffer layer 111 can reduce permeation of moisture or impurities through the first substrate 110. For example, the buffer layer 111 can be configured by a single layer or a double layer of silicon oxide SiOx or silicon nitride SiNx, but is not limited thereto. However, the buffer layer 111 can be omitted depending on a type of the first substrate 110 or a type of the thin film transistor, but is not limited thereto.

In FIGS. 6A to 6D, an additional buffer layer can be disposed between the first substrate 110 and the light shielding layer BSM. The additional buffer layer can be configured, for example, by a single layer or a double layer of silicon oxide SIOx or silicon nitride SiNx to reduce permeation of moisture or impurities through the first substrate 110, like the buffer layer 111.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT can be formed of a semiconductor material such as an oxide semiconductor, amorphous silicon, or polysilicon, but is not limited thereto. Further, other transistors, such as a switching transistor, a sensing transistor, and an emission control transistor, other than the driving transistor DT, can be further disposed. The active layers of the transistors can be also formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control transistor, can be formed of the same material, or formed of different materials.

A gate insulating layer 112 is disposed on the active layer ACT. The gate insulating layer 112 is an insulating layer which electrically insulates the active layer ACT from the gate electrode GE and can be configured by a single layer or a double layer of silicon oxide SiOx or silicon nitride SiNx, but is not limited thereto.

The gate electrode GE is disposed on the gate insulating layer 112. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact holes through which the source electrode SE and the drain electrode DE are connected to the active layer ACT are disposed. The first interlayer insulating layer 113 and the second interlayer insulating layer 114 are insulating layers which protect components therebelow and can be configured by single layers or double layers of silicon oxide SiOx or silicon nitride SiNx, but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode 130 and the drain electrode DE is connected to the other configuration of the pixel circuit. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a can be integrally disposed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a is disposed on the same layer as the light shielding layer BSM and can be formed of the same material.

The 2-2-th capacitor electrode C2b is disposed on the buffer layer 111 and the gate insulating layer 112. The 2-2-th capacitor electrode C2b can be disposed on the same layer as the gate electrode GE and can be formed of the same material.

The 2-3-th capacitor electrode C2c is disposed on the first interlayer insulating layer 113. The 2-3-th capacitor electrode C2c can be configured by a first layer C2c1 and a second layer C2c2. The first layer C2cl of the 2-3-th capacitor electrode C2c can be disposed on the same layer as the 1-2-th capacitor electrode C1b with the same material. The first layer C2cl can be disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and can be connected to the first layer C2cl through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and allow the light emitting diode 130 to emit light with a higher luminance.

A first passivation layer 115a is disposed on the driving transistor DT, the first capacitor C1, and the second capacitor C2. The first passivation layer 115a is an insulating layer which protects components below the first passivation layer 115a and can be configured by an inorganic material, such as silicon oxide SiOx or silicon nitride SiNx, but is not limited thereto.

A first planarization layer 116a is disposed on the first passivation layer 115a. The first planarization layer 116a can planarize an upper portion of the pixel circuit including the driving transistor DT. The first planarization layer 116a can be configured by a single layer or a double layer, and for example, configured by benzocyclobutene or an acrylic organic material, but is not limited thereto.

Referring to FIGS. 5A and 5B together, a plurality of reflection plates are disposed on the first planarization layer 116a. The reflection plate is a configuration which reflects light emitted from the plurality of light emitting diodes 130 above the first substrate 110 and can be disposed with a shape corresponding to each of the plurality of sub pixels SP. One reflection plate can be disposed to cover the most area of one sub pixel SP. The reflection plate can reflect the light emitted from the light emitting diode 130 and can be also used as an electrode which electrically connects the light emitting diode 130 and the pixel circuit.

Referring to FIGS. 5A, 5B, and FIG. 6A, the first reflection plate RF1 includes a 1-1-th reflection plate RF1a overlapping most of the first sub pixel SP1 and a 1-2-th reflection plate RF1b overlapping the red light emitting diode 130R of the first sub pixel SP1.

The 1-1-th reflection plate RF1a can reflect light emitted from the red light emitting diode 130R above the red light emitting diode 130R. The 1-1-th reflection plate RF1a can be electrically connected to the source electrode SE of the driving transistor DT and the second capacitor C2 through a first contact hole CH1 of the first planarization layer 116a and the first passivation layer 115a. Therefore, the 1-1-th reflection plate RF1a can electrically connect the driving transistor DT and the first electrode 134 of the red light emitting diode 130R.

The 1-2-th reflection plate RF1b can reflect light emitted from the red light emitting diode 130R above the red light emitting diode 130R. The 1-2-th reflection plate RF1b can serve as an electrode which electrically connects the second electrode 135 of the red light emitting diode 130R and the high potential power line VL1. Therefore, voltages applied to the second electrode 135 which is in contact with the second semiconductor layer 133 of the red light emitting diode 130R and the 1-2-th reflection plate RF1b disposed below the red light emitting diode 130R are the same high potential power voltage. Accordingly, a vertical electric field can not be generated between the 1-2-th reflection plate RF1b and the red light emitting diode 130R and the reliability problem caused by the vertical electric field can be suppressed.

In the meantime, the first reflection plate RF1 can include a first part RF1-1 and a second part RF1-2. The first reflection plate RF1 can include the first part RF1-1 overlapping a contact hole of an insulating layer disposed above the first reflection plate RF1 and the second part RF1-2 extending from the first part RF1-1.

The first part RF1-1 and the second part RF1-2 can be included in the 1-1-th reflection plate RF1a and the 1-2-th reflection plate RF1b, respectively. The second parts RF1-2 of the 1-1-th reflection plate RF1a and the 1-2-th reflection plate RF1b can reflect light emitted from the red light emitting diode 130R. In the meantime, the first part RF1-1 of the 1-1-th reflection plate RF1a can be also used as an electrode which electrically connects the red light emitting diode 130R and the pixel circuit. The first part RF1-1 of the 1-2-th reflection plate RF1b can be also used as an electrode which electrically connects the second electrode 135 of the red light emitting diode 130R and the high potential power line VL1. Therefore, the reflectance of the second part RF1-2 of the first reflection plate RF1 can be higher than the reflectance of the first part RF1-1 of the first reflection plate RF1.

Referring to FIG. 6A, the second part RF1-2 of the first reflection plate RF1 can include a plurality of layers L1, L2, L3, and L4. For example, the second part RF1-2 of the first reflection plate RF1 can include a first layer L1, a second layer L2 disposed on the first layer L1, a third layer L3 disposed on the second layer L2, and a fourth layer L4 disposed on the third layer L3. At this time, the second layer L2, the third layer L3, and the fourth layer L4 can be disposed to have the same area on the plane.

The first layer L1 and the fourth layer L4 can be formed of a transparent conductive oxide and the second layer L2 and the third layer L3 can be formed of a metal layer. At this time, the second layer L2 and the third layer L3 can be formed of a material having a reflectance higher than those of the first layer L1 and the fourth layer L4 and the third layer L3 can be formed of a material having a reflectance higher than that of the second layer L2. For example, the first layer L1 and the fourth layer L4 can be formed of indium tin oxide (ITO), the second layer L2 can be formed of molybdenum (Mo), and the third layer L3 can be formed of aluminum (Al).

The first part RF1-1 of the first reflection plate RF1 can include some of the plurality of layers L1, L2, L3, and L4. For example, the first part RF1-1 of the first reflection plate RF1 can include the first layer L1 of the plurality of layers L1, L2, L3, and L4. Therefore, the first part RF1-1 can be formed of indium tin oxide (ITO), but is not limited thereto.

Referring to FIGS. 5B and 6B, the second reflection plate RF2 includes a 2-1-th reflection plate RF2a overlapping most of the second sub pixel SP2 and a 2-2-th reflection plate RF2b overlapping the red light emitting diode 130R of the second sub pixel SP2.

The 2-1-th reflection plate RF2a can reflect light emitted from the red light emitting diode 130R above the red light emitting diode 130R. The 2-1-th reflection plate RF2a can be electrically connected to the source electrode SE of the driving transistor DT and the second capacitor C2 through a first contact hole CH1 of the first planarization layer 116a and the first passivation layer 115a. Therefore, the 2-1-th reflection plate RF2a can electrically connect the driving transistor DT and the first electrode 134 of the red light emitting diode 130R.

The 2-2-th reflection plate RF2b can reflect light emitted from the red light emitting diode 130R above the red light emitting diode 130R. The 2-2-th reflection plate RF2b can serve as an electrode which electrically connects the second electrode 135 of the red light emitting diode 130R and the high potential power line VL1. Therefore, voltages applied to the second electrode 135 which is in contact with the second semiconductor layer 133 of the red light emitting diode 130R and the 2-2-th reflection plate RF2b disposed below the red light emitting diode 130R are the same high potential power voltage. Accordingly, a vertical electric field can not be generated between the 2-2-th reflection plate RF2b and the red light emitting diode 130R and the reliability problem caused by the vertical electric field can be suppressed.

In the meantime, the second reflection plate RF2 can include a first part RF2-1 and a second part RF2-2. The second reflection plate RF2 can include the first part RF2-1 overlapping a contact hole of an insulating layer disposed above the second reflection plate RF2-2 and the second part RF2-2 extending from the first part RF2-1.

The first part RF2-1 and the second part RF2-2 can be included in the 2-1-th reflection plate RF2a and the 2-2-th reflection plate RF2b. The second parts RF2-2 of the 2-1-th reflection plate RF2a and the 2-2-th reflection plate RF2b can reflect light emitted from the red light emitting diode 130R. In the meantime, the first part RF2-1 of the 2-1-th reflection plate RF2a can be also used as an electrode which electrically connects the red light emitting diode 130R and the pixel circuit. The first part RF2-1 of the 2-2-th reflection plate RF2b can be also used as an electrode which electrically connects the second electrode 135 of the red light emitting diode 130R and the high potential power line VL1. Therefore, the reflectance of the second part RF2-2 of the 2-2-th reflection plate RF2b can be higher than the reflectance of the first part RF2-1 of the 2-2-th reflection plate RF2b.

Referring to FIG. 6B, the second part RF2-2 of the second reflection plate RF2 can include a plurality of layers L1, L2, L3, and L4. For example, the second part RF2-2 of the second reflection plate RF2 can include a first layer L1, a second layer L2 disposed on the first layer L1, a third layer L3 disposed on the second layer L2, and a fourth layer L4 disposed on the third layer L3. At this time, the second layer L2, the third layer L3, and the fourth layer L4 can be disposed to have the same area on the plane.

The first layer L1 and the fourth layer L4 are formed of a transparent conductive oxide and the second layer L2 and the third layer L3 can be formed of a metal layer. At this time, the second layer L2 and the third layer L3 can be formed of a material having a reflectance higher than those of the first layer L1 and the fourth layer L4 and the third layer L3 can be formed of a material having a reflectance higher than that of the second layer L2. For example, the first layer L1 and the fourth layer L4 can be formed of indium tin oxide (ITO), the second layer L2 can be formed of molybdenum (Mo), and the third layer L3 can be formed of aluminum (Al).

The first part RF2-1 of the second reflection plate RF2 can include some of the plurality of layers L1, L2, L3, and L4. For example, the first part RF2-1 of the second reflection plate RF2 can include the first layer L1 of the plurality of layers L1, L2, L3, and L4. Therefore, the first part RF2-1 can be configured by a layer formed of indium tin oxide (ITO), but is not limited thereto.

Referring to FIGS. 5A to 6C, the third reflection plate RF3 can reflect light emitted from the green light emitting diode 130G above the green light emitting diode 130G. Further, the third reflection plate RF3 can be electrically connected to the source electrode SE of the driving transistor DT and the second capacitor C2 through a first contact hole CH1 of the first planarization layer 116a and the first passivation layer 115a. Therefore, the third reflection plate RF3 can electrically connect the driving transistor DT and the first electrode 134 of the green light emitting diode 130G.

The third reflection plate RF3 can include a first part RF3-1 and a second part RF3-2. The third reflection plate RF3 can include a first part RF3-1 overlapping a contact hole of an insulating layer disposed above the third reflection plate RF3 and the second part RF3-2 extending from the first part RF3-1.

The second part RF3-2 of the third reflection part RF3 can reflect light emitted from the green light emitting diode 130G and the first part RF3-1 of the third reflection plate RF3 can be used as an electrode which electrically connects the green light emitting diode 130G and the pixel circuit. Therefore, the reflectance of the second part RF3-2 of the third reflection plate RF3 can be higher than the reflectance of the first part RF3-1 of the third reflection plate RF3. Further, voltages applied to the first electrode 134 which is in contact with the first semiconductor layer 131 of the green light emitting diode 130G and the third reflection plate RF3 disposed below the green light emitting diode 130G are the same output voltage of the driving transistor DT. Accordingly, a vertical electric field can not be generated between the third reflection plate RF3 and the green light emitting diode 130G and the reliability problem caused by the vertical electric field can be suppressed.

Referring to FIG. 6C, the second part RF3-2 of the third reflection plate RF3 can include a plurality of layers L1, L2, L3, and L4. For example, the second part RF3-2 of the third reflection plate RF3 can include a first layer L1, a second layer L2 disposed on the first layer L1, a third layer L3 disposed on the second layer L2, and a fourth layer L4 disposed on the third layer L3. At this time, the second layer L2, the third layer L3, and the fourth layer L4 can be disposed to have the same area on the plane.

The first layer L1 and the fourth layer L4 can be formed of a transparent conductive oxide and the second layer L2 and the third layer L3 can be formed of a metal layer. At this time, the second layer L2 and the third layer L3 can be formed of a material having a reflectance higher than those of the first layer L1 and the fourth layer L4 and the third layer L3 can be formed of a material having a reflectance higher than that of the second layer L2. For example, the first layer L1 and the fourth layer L4 can be formed of indium tin oxide (ITO), the second layer L2 can be formed of molybdenum (Mo), and the third layer L3 can be formed of aluminum (Al).

The first part RF3-1 of the third reflection plate RF3 can include some of the plurality of layers L1, L2, L3, and L4. For example, the first part RF3-1 of the third reflection plate RF3 can include the first layer L1 of the plurality of layers L1, L2, L3, and L4. Therefore, the first part RF3-1 can be configured by a layer formed of indium tin oxide (ITO), but is not limited thereto.

Referring to FIGS. 5A, 5B, and 6D, the fourth reflection plate RF4 can reflect light emitted from the blue light emitting diode 130B above the blue light emitting diode 130B. Further, the fourth reflection plate RF4 can be electrically connected to the source electrode SE of the driving transistor DT and the second capacitor C2 through a first contact hole CH1 of the first planarization layer 116a and the first passivation layer 115a. Therefore, the fourth reflection plate RF4 can electrically connect the driving transistor DT and the first electrode 134 of the blue light emitting diode 130B.

The fourth reflection plate RF4 can include a first part RF4-1 and a second part RF4-2. The fourth reflection plate RF4 can include a first part RF4-1 overlapping a contact hole of an insulating layer disposed above the fourth reflection plate RF4 and a second part RF4-2 extending from the first part RF4-1.

The second part RF4-2 of the fourth reflection part RF4 can reflect light emitted from the blue light emitting diode 130B and the first part RF4-1 of the fourth reflection plate RF4 can be used as an electrode which electrically connects the blue light emitting diode 130B and the pixel circuit. Therefore, the reflectance of the second part RF4-2 of the fourth reflection plate RF4 can be higher than the reflectance of the first part RF4-1 of the fourth reflection plate RF4. Further, voltages applied to the first electrode 134 which is in contact with the first semiconductor layer 131 of the blue light emitting diode 130B and the fourth reflection plate RF4 disposed below the blue light emitting diode 130B are the same output voltage of the driving transistor DT. Accordingly, a vertical electric field can not be generated between the fourth reflection plate RF4 and the blue light emitting diode 130B and the reliability problem caused by the vertical electric field can be suppressed.

Referring to FIG. 6D, the second part RF4-2 of the fourth reflection plate RF4 can include a plurality of layers L1, L2, L3, and L4. For example, the second part RF4-2 of the fourth reflection plate RF4 can include a first layer L1, a second layer L2 disposed on the first layer L1, a third layer L3 disposed on the second layer L2, and a fourth layer L4 disposed on the third layer L3. At this time, the second layer L2, the third layer L3, and the fourth layer L4 can be disposed to have the same area on the plane.

The first layer L1 and the fourth layer L4 can be formed of a transparent conductive oxide and the second layer L2 and the third layer L3 can be formed of a metal layer. At this time, the second layer L2 and the third layer L3 can be formed of a material having a reflectance higher than those of the first layer L1 and the fourth layer L4 and the third layer L3 can be formed of a material having a reflectance higher than that of the second layer L2. For example, the first layer L1 and the fourth layer L4 can be formed of indium tin oxide (ITO), the second layer L2 can be formed of molybdenum (Mo), and the third layer L3 can be formed of aluminum (Al).

The first part RF4-1 of the fourth reflection plate RF4 can include some of the plurality of layers L1, L2, L3, and L4. For example, the first part RF4-1 of the fourth reflection plate RF4 can include the first layer L1 of the plurality of layers L1, L2, L3, and L4. Therefore, the first part RF4-1 can be configured by a layer formed of indium tin oxide (ITO), but is not limited thereto.

In the meantime, even though it has been described that the first sub pixel SP1 and the second sub pixel SP2 are formed with two reflection plates and the third sub pixel SP3 and the fourth sub pixel SP4 are formed with one reflection plate, the reflection plate can be designed in various manners. For example, only one reflection plate can be disposed in all the plurality of sub pixels SP, like the third sub pixel SP3 and the fourth sub pixel SP4 or a plurality of reflection plates can be disposed in the sub pixels like the first sub pixel SP1 and the second sub pixel SP2, but the reflection plate is not limited thereto.

Referring to FIGS. 6A to 6D, a second passivation layer 115b is disposed on the plurality of reflection plates. The second passivation layer 115b is an insulating layer which protects components below the second passivation layer 115b and can be configured by a single layer or a double layer of silicon oxide SiOx or silicon nitride SiNx, but is not limited thereto.

An adhesive layer AD is disposed on the second passivation layer 115b. The adhesive layer AD is disposed between the plurality of reflection plates and the plurality of light emitting diodes 130 to fix the light emitting diode 130 disposed on the front surface of the first substrate 110 to be disposed on the adhesive layer AD. The adhesive layer AD can be formed of a photo curable adhesive material which is cured by light. For example, the adhesive layer AD can be formed of an acrylic material including a photoresist, but is not limited thereto. The adhesive layer AD can be disposed on the entire surface of the first substrate 110 excluding a pad area in which the first pad electrode PAD1 is disposed.

The plurality of light emitting diodes 130 is disposed in each of the plurality of sub pixels SP on the adhesive layer AD. The light emitting diode 130 is an element which emits light by a current and can include a red light emitting diode 130R which emits red light, a green light emitting diode 130G which emits green light, and a blue light emitting diode 130B which emits blue light and can implement light with various colors including white by a combination thereof. For example, the light emitting diode 130 can be a light emitting diode (LED) or a micro LED, but is not limited thereto.

In the meantime, the light emitting diode 130 disposed in each of the plurality of sub pixels SP can have a different structure. For example, the light emitting diode 130 can include red light emitting diodes 130R disposed on the first sub pixel SP1 and the second sub pixel SP2, a green light emitting diode 130G disposed on the third sub pixel SP3, and a blue light emitting diode 130B disposed on the fourth sub pixel SP4. For example, one red light emitting diode 130R can be disposed in each of the first sub pixel SP1 and the second sub pixel SP2, one pair of green light emitting diodes 130G can be disposed in the third sub pixel SP3, and one pair of blue light emitting diodes 130B can be disposed in the fourth sub pixel SP4. That is, two red light emitting diodes 130R, two green light emitting diodes 130G, and two blue light emitting diodes 130B can be disposed in one pixel PX. At this time, the red light emitting diode 130R can have a structure different from those of the green light emitting diode 130G and two blue light emitting diodes 130B. Each of the red light emitting diodes 130R is connected to the driving transistor DT of each of the first sub pixel SP1 and the second sub pixel SP2 to be individually driven. In contrast, one pair of green light emitting diodes 130G of the third sub pixel SP3 and one pair of blue light emitting diodes 130B of the fourth sub pixel SP4 are connected to one driving transistor DT in parallel to be driven.

First, referring to FIGS. 6A and 6B, the red light emitting diode 130R is disposed in the first sub pixel SP1 and the second sub pixel SP2. The red light emitting diode 130R includes a first semiconductor layer 131, an emission layer 132, a second semiconductor layer 133, a first electrode 134, a second electrode 135, and an encapsulation layer 136.

In the red light emitting diode 130R, the second semiconductor layer 133 can be disposed on the adhesive layer AD and the first semiconductor layer 131 can be disposed on the second semiconductor layer 133.

The emission layer 132 is disposed between the first semiconductor layer 131 and the second semiconductor layer 133 in the red light emitting diode 130R. The emission layer 132 is supplied with holes and electrons from the first semiconductor layer 131 and the second semiconductor layer 133 to emit light. The emission layer 132 can be formed by a single layer or a multi-quantum well (MQW) structure, and for example, can be formed of indium gallium nitride (InGaN) or gallium nitride (GaN), but is not limited thereto.

The second electrode 135 is disposed on the second semiconductor layer 133 in the red light emitting diode 130R. The second electrode 135 is an electrode which electrically connects the high potential power line VL1 and the second semiconductor layer 133.

In the red light emitting diode 130R, the second semiconductor layer 133 is a semiconductor layer doped with a p-type impurity, such as magnesium, zinc (Zn), and beryllium (Be) and the second electrode 135 can be a cathode.

In the red light emitting diode 130R, the second electrode 135 can be disposed on a top surface of the second semiconductor layer 133 exposed from the emission layer 132 and the first semiconductor layer 131. The second electrode 135 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 134 is disposed on the first semiconductor layer 131 in the red light emitting diode 130R. The first electrode 134 can be disposed on the top surface of the first semiconductor layer 131. The first electrode 134 is an electrode which electrically connects the driving transistor DT and the first semiconductor layer 131. In this case, the first semiconductor layer 131 is a semiconductor layer doped with an n-type impurity, such as silicon (Si), germanium, or tin (Sn) and the first electrode 134 can be an anode. The first electrode 134 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

In the red light emitting diode 130R, the encapsulation layer 136 which encloses the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is disposed to electrically connect a first connection electrode CE1 and a second connection electrode CE2 to the first electrode 134 and the second electrode 135.

Next, referring to FIG. 6C, the green light emitting diode 130G is disposed in the third sub pixel SP3. The green light emitting diode 130G includes a first semiconductor layer 131, an emission layer 132, a second semiconductor layer 133, a first electrode 134, and a second electrode 135.

The green light emitting diode 130G can have a structure different from that of the red light emitting diode 130R. For example, in the green light emitting diode 130G, the first semiconductor layer 131 can be disposed on the adhesive layer AD and the second semiconductor layer 133 can be disposed on the first semiconductor layer 131.

In the green light emitting diode 130G, the first semiconductor layer 131 and the second semiconductor layer 133 can be layers formed by doping n-type and p-type impurities into a specific material. For example, the first semiconductor layer 131 and the second semiconductor layer 133 can be layers doped with n-type and p-type impurities into a material such as gallium nitride (GaN), indium aluminum phosphide (InAlP), or gallium arsenide (GaAs). The p-type impurity can be magnesium (Mg), zinc (Zn), beryllium (Be), and the like, and the n-type impurity can be silicon (Si), germanium, tin (Sn), and the like, but are not limited thereto.

The emission layer 132 is disposed between the first semiconductor layer 131 and the second semiconductor layer 133 in the green light emitting diode 130G. The emission layer 132 is supplied with holes and electrons from the first semiconductor layer 131 and the second semiconductor layer 133 to emit light. The emission layer 132 can be formed by a single layer or a multi-quantum well (MQW) structure, and for example, can be formed of indium gallium nitride (InGaN), gallium nitride (GaN), or the like, but is not limited thereto.

The first electrode 134 is disposed on the first semiconductor layer 131 in the green light emitting diode 130G. The first electrode 134 is an electrode which electrically connects the driving transistor DT and the first semiconductor layer 131. In the green light emitting diode 130G, the first semiconductor layer 131 is a semiconductor layer doped with an n-type impurity and the first electrode 134 can be a cathode. The first electrode 134 can be disposed on a top surface of the first semiconductor layer 131 which is exposed from the emission layer 132 and the second semiconductor layer 133. The first electrode 134 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133 in the green light emitting diode 130G. The second electrode 135 can be disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 can be an anode. The second electrode 135 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, in the green light emitting diode 130G, the encapsulation layer 136 which encloses the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is disposed to electrically connect a first connection electrode CE1 and a second connection electrode CE2 to the first electrode 134 and the second electrode 135.

Referring to FIG. 5D, the blue light emitting diode 130B is disposed in the fourth sub pixel SP4. The blue light emitting diode 130B includes a first semiconductor layer 131, an emission layer 132, a second semiconductor layer 133, a first electrode 134, and a second electrode 135.

The blue light emitting diode 130B can have a structure different from that of the red light emitting diode 130R. For example, the blue light emitting diode 130B can have the same structure as the green light emitting diode 130G disposed in the third sub pixel SP3 so that a redundant description will be omitted.

In the meantime, referring to FIGS. 6A to 6D, a part of the side surface of the first semiconductor layer 131 can be exposed from the encapsulation layer 136. The light emitting diode 130 manufactured on the wafer is separated from the wafer to be transferred onto the display panel PN. However, during the process of separating the light emitting diode 130 from the wafer, a part of the encapsulation layer 136 can be torn. For example, a part of the encapsulation layer 136 which is adjacent to a lower edge of the first semiconductor layer 131 of the light emitting diode 130 is torn during the process of separating the light emitting diode 130 from the wafer. Accordingly, a part of a lower side surface of the first semiconductor layer 131 can be exposed to the outside. However, even though the lower portion of the light emitting diode 130 is exposed from the encapsulation layer 136, the first connection electrode CE1 and the second connection electrode CE2 are formed after forming the second planarization layer 116b and the third planarization layer 116c which cover the side surface of the first semiconductor layer 131. Accordingly, a short problem can be reduced.

Next, referring to FIGS. 6A to 6D, the second planarization layer 116b and the third planarization layer 116c are disposed on the adhesive layer AD and the light emitting diode 130.

The second planarization layer 116b overlaps a part of side surfaces of the plurality of light emitting diodes 130 to fix and protect the plurality of light emitting diodes 130. The second planarization layer 116b can be formed using a halftone mask. Therefore, the second planarization layer 116b can be formed to have a step.

Specifically, a part of the second planarization layer 116b which is relatively adjacent to the light emitting diode 130 can have a smaller thickness and a part which is farther from the light emitting diode 130 can have a larger thickness. A part of the second planarization layer 116b which is adjacent to the light emitting diode 130 can be disposed to enclose the light emitting diode 130 and also can be in contact with a side surface of the light emitting diode 130. Therefore, a torn part of the encapsulation layer 136 which protects a side surface of the first semiconductor layer 131 of the light emitting diode 130 during the process of separating the light emitting diode 130 from the wafer to be transferred onto the display panel PN can be covered by the second planarization layer 116b. By doing this, thereafter, contacts and short problems of the connection electrodes CE1 and CE2 and the first semiconductor layer 131 can be suppressed.

The third planarization layer 116c is disposed to cover upper portions of the second planarization layer 116b and the light emitting diode 130 and a contact hole which exposes the first electrode 134 and the second electrode 135 of the light emitting diode 130 can be formed. The first electrode 134 and the second electrode 135 of the light emitting diode 130 are exposed from the third planarization layer 116c and the third planarization layer 116c is partially disposed in an area between the first electrode 134 and the second electrode 135 to reduce a short problem. The second planarization layer 116b and the third planarization layer 116c can be configured by a single layer or a double layer, and for example, can be formed of photoresist or an acrylic organic material, but is not limited thereto.

In the meantime, the third planarization layer 116c can cover only the light emitting diode 130 and an area adjacent to the light emitting diode 130. The third planarization layer 116c is disposed in an area of the sub pixel SP enclosed by the bank BB and can be disposed in an island shape. Therefore, the bank BB can be disposed in a part of the top surface of the second planarization layer 116b and the third planarization layer 116c can be disposed in the other part of the top surface of the second planarization layer 116b.

The first connection electrode CE1 and the second connection electrode CE2 are disposed on the third planarization layer 116c. The first connection electrode CE1 is an electrode which electrically connects the second electrode 135 of the light emitting diode 130 and the high potential power line VL1. The first connection electrode CE1 can be electrically connected to the second electrode 135 of the light emitting diode 130 through a contact hole disposed in the third planarization layer 116c. Further, the first connection electrode can be in contact with the reflection plate through a contact hole disposed in the third planarization layer 116c, the second planarization layer 116b, the adhesive layer AD, and the second passivation layer 115b.

In the meantime, the first part RF1-1 of the 1-1-th reflection plate RF1a, the first part RF1-1 of the 1-2-th reflection plate RF1b, the first part RF2-1 of the 2-1-th reflection plate RF2a, the first part RF2-1 of the 2-2-th reflection plate RF2b, the first part RF3-1 of the third reflection plate RF3, and the first part RF4-1 of the fourth reflection plate RF4 of the reflection plate can be in contact with the plurality of first connection electrodes CE1 and second connection electrode CE2.

The first connection electrode CE1 can be in contact with the 1-2-th reflection plate RF1b, the 2-2-th reflection plate RF2b, the third reflection plate RF3, and the fourth reflection plate RF4 of each of the plurality of sub pixels SP which is exposed through contact holes disposed in the first protection layer 117, the third planarization layer 116c, the second planarization layer 116b, the adhesive layer AD, and the second passivation layer 115b. At this time, the contact hole can be disposed in an area overlapping the first part RF1-1 of the 1-2-th reflection plate RF1b, the first part RF2-1 of the 2-2-th reflection plate RF2b, the first part RF3-1 of the third reflection plate RF3, and the first part RF4-1 of the fourth reflection plate RF4 of the reflection plate.

For example, each of the first connection electrodes CE1 can electrically connect the 1-2-th reflection plate RF1b to the second electrode 135 of the red light emitting diode 130R disposed in the first sub pixel SP1 and the 2-2-reflection plate RF2b to the second electrode 135 of the red light emitting diode 130R disposed in the second sub pixel SP2.

The second connection electrode CE2 is an electrode which electrically connects the first electrode 134 of the light emitting diode 130 and the driving transistor DT. The second connection electrode CE2 can be in contact with the 1-1-th reflection plate RF1a, the 2-1-th reflection plate RF2a, the third reflection plate RF3, and the fourth reflection plate RF4 of each of the plurality of sub pixels SP which is exposed through contact holes disposed in the first protection layer 117, the third planarization layer 116c, the second planarization layer 116b, the adhesive layer AD, and the second passivation layer 115b. At this time, the contact hole can be disposed in an area overlapping the first part RF1-1 of the 1-1-th reflection plate RF1a, the first part RF2-1 of the 2-1-th reflection plate RF2a, the first part RF3-1 of the third reflection plate RF3, and the first part RF4-1 of the fourth reflection plate RF4 of the reflection plate.

For example, the second connection electrode CE2 can electrically connect the first electrode 134 of the green light emitting diode 130G disposed in the third sub pixel SP3 and the third reflection plate RF3. The second connection electrode CE2 can electrically connect the first electrode 134 of the blue light emitting diode 130B disposed in the fourth sub pixel SP4 and the fourth reflection plate RF4.

The 1-1-th reflection plate RF1a, the 2-1-th reflection plate RF2a, the third reflection plate RF3, and the fourth reflection plate RF4 are also connected to the source electrode SE of the driving transistor DT. Therefore, the source electrode SE of the driving transistor DT and the first electrode 134 of the light emitting diode 130 can be electrically connected to each other.

In the meantime, in the drawing, it is illustrated that the first electrode 134, the second connection electrode CE2, and the reflection plate are electrically connected to the source electrode SE of the driving transistor DT. However, the first electrode 134, the second connection electrode CE2, and the reflection plate can be connected to the drain electrode DE of the driving transistor DT, but it is not limited thereto.

A bank BB is disposed on the second planarization layer 116b exposed from the first connection electrode CE1 and the second connection electrode CE2, and the third planarization layer 116c. The bank BB can be disposed to be spaced apart from the light emitting diode 130 with a predetermined interval and can overlap at least partially the reflection plate RF. For example, the bank BB can cover a part of the second connection electrode CE2 disposed in the contact holes of the third planarization layer 116c and the second planarization layer 116b. Further, for example, the bank BB can be disposed on the second planarization layer 116b with a predetermined interval from the light emitting diode 130. In this case, the bank BB and the third planarization layer 116c can be spaced apart from each other on a part of the second planarization layer 116b having a smaller thickness. That is, an end of the bank BB and an end of the third planarization layer 116c can be disposed on a part of the second planarization layer 116b having a smaller thickness formed by a halftone mask process to be spaced apart from each other.

The bank BB can be formed of an opaque material to reduce color mixture between the plurality of sub pixels SP and for example, can be formed of black resin, but is not limited thereto.

In the meantime, a thickness of a part of the bank BB which is disposed in the contact holes of the third planarization layer 116c and the second planarization layer 116b to cover a part of the second connection electrode CE2 and a thickness of a part disposed on the second planarization layer 116b can be different from each other. Specifically, when the part of the bank BB covers a part of the second connection electrode CE2 disposed in the contact holes of the third planarization layer 116c and the second planarization layer 116b, since the contact hole is disposed from the second passivation layer 115b to the third planarization layer 116c, the bank BB can be disposed below the light emitting diode 130, that is, disposed to be lower than the light emitting diode 130. Therefore, the thickness of the part of the bank BB which covers a part of the second connection electrode CE2 disposed in the contact holes of the third planarization layer 116c and the second planarization layer 116b can be larger than the thickness of a part of the bank BB disposed on the second planarization layer 116b.

A first protection layer 117 is disposed on the first connection electrode CE1, the second connection electrode CE2, and the bank BB. The first protection layer 117 is a layer for protecting a configuration below the first protection layer 117 and for example, can cover at least a part of the light emitting diode 130. The first protective layer 117 can be configured by a single layer or a double layer of translucent epoxy, silicon oxide SiOx or silicon nitride SiNx, but is not limited thereto.

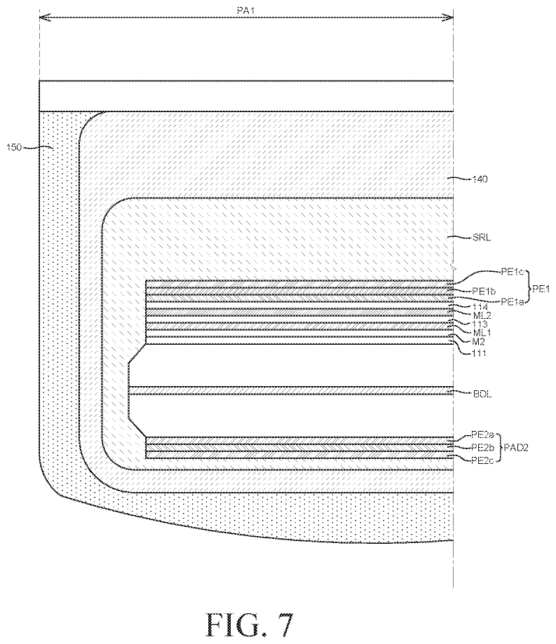

FIG. 7 is a cross-sectional view of a pad area of a display device according to an example embodiment of the present disclosure.

Referring to FIG. 7, a plurality of first pad electrodes PAD1 are disposed in a first pad area PA1 of the first substrate 110. Each of the plurality of first pad electrodes PAD1 can be configured by a plurality of conductive layers. For example, each of the plurality of first pad electrodes PAD1 include a first conductive layer PE1a, a second conductive layer PE1b, and a third conductive layer PE1c.

First, the first conductive layer PE1a is disposed on the second interlayer insulating layer 114. The first conductive layer PE1a can be formed of the same conductive material as the source electrode SE and the drain electrode DE and for example, can be configured by copper (Cu), aluminum (Al), molybdenum (Mo), nickel (Ni), titanium (Ti), chrome (Cr), or an alloy thereof, but is not limited thereto.

A second conductive layer PE1b is disposed on the first conductive layer PE1a. The second conductive layer PE1b can be formed of the same conductive material as the reflection plate. For example, the second conductive layer PE1b includes a conductive layer formed of the same material as the first parts RF1-1 of the 1-1-th reflection plate RF1a and the 1-2-th reflection plate RF1b, the first parts RF2-1 of the 2-1-th reflection plate RF2a and the 2-2-th reflection plate RF2b, the first part RF3-1 of the third reflection plate RF3, and the first part RF4-1 of the fourth reflection plate RF4 of the reflection plate. That is, the second conductive layer PE1b can be configured by a first layer L1 formed of indium tin oxide (ITO), but is not limited thereto.

The third conductive layer PE1c is disposed on the second conductive layer PE1b. The third conductive layer PE1c can be formed of the same conductive material as the first connection electrode CE1 and the second connection electrode CE2, and for example, a transparent conductive material, such as indium tin oxide (ITO) or indium zinc oxide (IZO), but is not limited thereto.

At this time, a part of the plurality of conductive layers of the first pad electrode PAD1 are electrically connected to a plurality of wiring lines on the first substrate 110 to supply various signals to a plurality of wiring lines and a plurality of sub pixels SP. For example, the first conductive layer PE1a and/or the second conductive layer PE1b of the first pad electrode PAD1 is connected to the data line DL, the high potential power line VL1, and the low potential power line VL2 disposed in the active area AA to transmit signals thereto.

A first metal layer ML1, a second metal layer ML2, and a plurality of insulating layers can be disposed together below the first pad electrode PAD1. The first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 can be sequentially disposed between the first pad electrode PAD1 and the first substrate 110. The first metal layer ML1 can be formed of the same conductive material as the gate electrode GE and the second metal layer ML2 can be formed of the same conductive material as the 1-2-th capacitor electrode C1b. However, the plurality of insulating layers, the first metal layer ML1, and the second metal layer ML2 below the first pad electrode PAD1 can be omitted depending on a design and are not limited thereto.

A second substrate 120 is disposed below the first substrate 110. The second substrate 120 is a substrate which supports components disposed below the display device 100 and can be an insulating substrate. For example, the second substrate 120 can be formed of glass, resin, or the like. Further, the second substrate 120 can include polymer or plastic. The second substrate 120 can be formed of the same material as the first substrate 110. In some example embodiments, the second substrate 120 can be formed of a plastic material having flexibility.

A bonding layer BDL is disposed between the first substrate 110 and the second substrate 120. The bonding layer BDL can be formed of a material which is cured by various curing methods to bond the first substrate 110 and the second substrate 120. The bonding layer BDL can be disposed only in a partial area between the first substrate 110 and the second substrate 120 or can be disposed in the entire area therebetween.

A plurality of second pad electrodes PAD2 are disposed on a rear surface of the second substrate 120. The plurality of second pad electrodes PAD2 are electrodes which transmit a signal from a driving component disposed on the rear surface of the second substrate 120 to a plurality of side lines SRL and a plurality of first pad electrodes PAD1 and a plurality of wiring lines on the first substrate 110. The plurality of second pad electrodes PAD2 are disposed in an end portion of the second substrate 120 in the non-active area NA to be electrically connected to the side line SRL which covers the end portion of the second substrate 120.

At this time, the plurality of second pad electrodes PAD2 can be also disposed so as to correspond to the plurality of pad areas. The plurality of first pad electrodes PAD1 can be disposed to correspond to the plurality of second pad electrodes PAD2, respectively, and then the first pad electrode PAD1 and the second pad electrode PAD2 which overlap each other can be electrically connected through the side line SRL.

Each of the plurality of second pad electrodes PAD2 include a plurality of conductive layers. For example, each of the plurality of second pad electrodes PAD2 include a fourth conductive layer PE2a, a fifth conductive layer PE2b, and a sixth conductive layer PE2c.

First, the fourth conductive layer PE2a is disposed below the second substrate 120. The fourth conductive layer PE2a can be configured by a conductive material such as copper (Cu), aluminum (Al), molybdenum (Mo), nickel (Ni), titanium (Ti), chrome (Cr), or an alloy thereof, but is not limited thereto.

The fifth conductive layer PE2b is disposed below the fourth conductive layer PE2a. The fifth conductive layer PE2b can be configured by a conductive material, such as copper (Cu), aluminum (Al), molybdenum (Mo), nickel (Ni), titanium (Ti), chrome (Cr), or an alloy thereof, but is not limited thereto.

The sixth conductive layer PE2c is disposed below the fifth conductive layer PE2b. The sixth conductive layer PE2c can be formed of a conductive material, for example, a transparent conductive material, such as indium tin oxide (ITO) or indium zinc oxide (IZO), but is not limited thereto.

The second protection layer 121 is disposed in the remaining area of the second substrate 120. The second protection layer 121 can protect various wiring lines and driving components disposed on the second substrate 120. The second protection layer 121 can be configured by an organic insulating material, and for example, configured by benzocyclobutene or an acrylic organic insulating material, but is not limited thereto.

A driving component including a plurality of flexible films and a printed circuit board can be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC can be disposed.

For example, the fourth conductive layer PE2a and/or the fifth conductive layer PE2b of the second pad electrode PAD2 extend to the plurality of flexible films disposed on the rear surface of the second substrate 120 to be electrically connected to the plurality of flexible films. The plurality of flexible films can supply various signals to the plurality of side lines SRL, the plurality of first pad electrodes PAD1, the plurality of wiring lines, and the plurality of sub pixels SP through the second pad electrode PAD2. Therefore, the signal from the driving component can be transmitted to the signal line and the plurality of sub pixels SP on the front surface of the first substrate 110 through the plurality of second pad electrodes PAD2 of the second substrate 120, the side line SRL, and the plurality of first pad electrodes PAD1 of the first substrate 110.

In FIG. 7, the second pad area PA2 can be also disposed with the same structure as the first pad area PA1.

Next, the plurality of side lines SRL are disposed on the side surfaces of the first substrate 110 and the second substrate 120. The plurality of side lines SRL can electrically connect the plurality of first pad electrodes PAD1 disposed on the top surface of the first substrate 110 and the plurality of second pad electrodes PAD2 disposed on the rear surface of the second substrate 120. The plurality of side lines SRL can be disposed so as to enclose the side surface of the display device 100. Each of the plurality of side lines SRL can cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL can be formed by a pad printing method using a conductive ink, for example, including silver (Ag), copper (Cu), molybdenum (Mo), and chrome (Cr).

A side insulating layer 140 which covers the plurality of side lines SRL is disposed. The side insulating layer 140 can be disposed on the top surface of the first substrate 110, the side surface of the first substrate 110, the side surface of the second substrate 120, and the rear surface of the second substrate 120 to cover the side line SRL. The side insulating layer 140 can protect the plurality of side lines SRL.

In the meantime, when the plurality of side lines SRL are formed of a metal material, there can be a problem in that external light is reflected from the plurality of side lines SRL or light emitted from the light emitting diode 130 is reflected from the plurality of side lines SRL to be visibly recognized by the user. Therefore, the side insulating layer 140 is configured to include a black material to suppress reflection of the external light. For example, the side insulating layer 140 can be formed by a pad printing method using an insulating material including a black material, for example, a black ink.

A seal member 150 which covers the side insulating layer 140 is disposed. The seal member 150 is disposed so as to enclose the side surface of the display device 100 to protect the display device 100 from external impacts, moisture and oxygen, or the like. For example, the seal member 150 can be formed of polyimide (PI), poly urethane, epoxy, or acryl based insulating material, but is not limited thereto.

An optical film MF is disposed on the seal member 150, the side insulating layer 140, and the first protection layer 117. The optical film MF can be a functional film which implements a higher quality of images while protecting the display device 100. For example, the optical film MF can include an anti-scattering film, an anti-glare film, an anti-reflecting film, a low-reflecting film, an OLED transmittance controllable film, a polarizer, or the like, but is not limited thereto.

In the meantime, an adhesive layer can be further disposed between the optical film MF and the seal member 150 and the side insulating layer 140 and the first protection layer 117, in FIGS. 6A to 7. Alternatively, the optical film MF can be also defined to include an adhesive layer disposed therebelow.

An edge of the seal member 150 and an edge of the optical film MF can be disposed on the same line. The optical film MF having a larger size is attached above the first substrate 110 during the manufacturing process of the display device 100 and the seal member 150 which covers the side insulating layer 140 can be formed. Thereafter, laser is irradiated on the seal member 150 and the optical film MF so as to correspond to an edge of the display device 100 to cut a part of the seal member 150 and the optical film MF. Accordingly, the size of the display device 100 can be adjusted by an outer periphery cutting process of the seal member 150 and the optical film MF and the edge of the display device 100 can be disposed to be flat.

Since the light formed in the emission layer of the light emitting diode is emitted to all the directions so that light excluding light emitted to the front surface of the panel is not emitted, but can be lost. Therefore, the reflection plate is located below the light emitting diode to reflect the light emitted from the emission layer toward the front surface of the panel, thereby improving the reflectance of the display device. Further, the electrode of the light emitting diode and the driving circuit and the signal line can be electrically connected by means of the reflection plate. Therefore, the reflection plate also serves as an electrode. Accordingly, the reflection plate requires a low resistance together with a high reflectance and also requires a reliability for long-term driving.

However, there are limitations in satisfying both the electrical characteristic and the optical characteristic described above. For example, when an aluminum alloy is disposed between the transparent electrodes to be used as a reflection plate, the reflectance is high, but aluminum ions precipitate during high-temperature operation, causing electrical connection between other electrodes and the reflection plate in the display device. Therefore, when an aluminum metal and a transparent electrode on the aluminum metal are disposed to be used as a reflection plate, the reflectance is high. However, an aluminum oxide film Al₂O₃ is naturally generated between the indium tin oxide ITO which is widely used for the transparent electrode and aluminum (Al). Further, the aluminum oxide film Al₂O₃ serves as an insulator. Accordingly, there can be problems in that the electrical characteristic is degraded and a screen failure can be caused during the panel operation. Therefore, when a structure in which a molybdenum metal layer is inserted between indium tin oxide (ITO) which is a transparent electrode and aluminum (Al), thereabove and/or therebelow is used as the reflection plate, the above-described formation of the aluminum oxide film Al₂O₃ is reduced to suppress the degradation of the electrical characteristic. However, molybdenum (Mo) has a problem of lower reflectance than the other metal layers and a low electric conductivity.

Therefore, in the display device 100 according to the example embodiment of the present disclosure, the reflection plate is disposed with a dual structure. For example, the second part RF1-2 of the 1-1-th reflection plate RF1a, the second part RF1-2 of the 1-2-th reflection plate RF1b, the second part RF2-2 of the 2-1-th reflection plate RF2a, the second part RF2-2 of the 2-2-th reflection plate RF2b, the second part RF3-2 of the third reflection plate RF3, and the second part RF4-2 of the fourth reflection plate RF4 overlap the red light emitting diode 130R, the green light emitting diode 130G, and the blue light emitting diode 130B to mainly serve to reflect light emitted from the red light emitting diode 130R, the green light emitting diode 130G, and the blue light emitting diode 130B. Further, the first part RF1-1 of the 1-1-th reflection plate RF1a, the first part RF1-1 of the 1-2-th reflection plate RF1b, the first part RF2-1 of the 2-1-th reflection plate RF2a, the first part FR2-1 of the 2-2-th reflection plate RF2b, the first part RF3-1 of the third reflection plate RF3, and the first part RF4-1 of the fourth reflection plate RF4 mainly serve to provide electrical connection. The second part RF1-2 of the 1-1-th reflection plate RF1a, the second part RF1-2 of the 1-2-th reflection plate RF1b, the second part RF2-2 of the 2-1-th reflection plate RF2a, the second part RF2-2 of the 2-2-th reflection plate RF2b, the second part RF3-2 of the third reflection plate RF3, and the second part RF4-2 of the fourth reflection plate RF4 and the first part RF1-1 of the 1-1-th reflection plate RF1a, the first part RF1-1 of the 1-2-th reflection plate RF1b, the first part RF2-1 of the 2-1-th reflection plate RF2a, the first part RF2-1 of the 2-2-th reflection plate RF2b, the first part RF3-1 of the third reflection plate RF3, and the first part RF4-1 of the fourth reflection plate RF4 can have different laminated structures. For example, the second part RF1-2 of the 1-1-th reflection plate RF1a, the second part RF1-2 of the 1-2-th reflection plate RF1b, the second part RF2-2 of the 2-1-th reflection plate RF2a, the second part RF2-2 of the 2-2-th reflection plate RF2b, the second part RF3-2 of the third reflection plate RF3, and the second part RF4-2 of the fourth reflection plate RF4 include a first layer L1 formed of indium tin oxide (ITO), a second layer L2 which is formed of molybdenum (Mo) to suppress the oxidation of aluminum (Al), a third layer L3 which is formed of aluminum (Al) having a reflectance higher than that of molybdenum (Mo), and a fourth layer L4 formed of indium tin oxide (ITO). Therefore, the light emitted from the light emitting diode 130 can be efficiently reflected above the display device 100 through the third layer L3 having a high reflectance. Further, the first part RF1-1 of the 1-1-th reflection plate RF1a, the first part RF1-1 of the 1-2-th reflection plate RF1b, the first part RF2-1 of the 2-1-th reflection plate RF2a, the first part RF2-1 of the 2-2-th reflection plate RF2b, the first part RF3-1 of the third reflection plate RF3, and first part RF4-1 of the fourth reflection plate RF4 include a first layer L1 formed of indium tin oxide (ITO), but do not include a second layer L2 and a third layer L3 which are formed of molybdenum (Mo) and aluminum (Al). Therefore, the generation of aluminum oxide film Al₂O₃ between aluminum (Al) and indium tin oxide (ITO) is suppressed to improve the electrical characteristic. Therefore, in the display device 100 according to the example embodiment of the present disclosure, in the area overlapping the light emitting diode 130, the light emission efficiency of the display device 100 can be increased by the high reflectance of the second part RF1-2 of the 1-1-th reflection plate RF1a, the second part RF1-2 of the 1-2-th reflection plate RF1b, the second part RF2-2 of the 2-1-th reflection plate RF2a, the second part RF2-2 of the 2-2-th reflection plate RF2b, the second part RF3-2 of the third reflection plate RF3, and the second part RF4-2 of the fourth reflection plate RF4. Further, the electrical characteristic of the display device 100 can be improved by the first part RF1-1 of the 1-1-th reflection plate RF1a, the first part RF1-1 of the 1-2-th reflection plate RF1b, the first part RF2-1 of the 2-1-th reflection plate RF2a, the first part RF2-1 of the 2-2-th reflection plate RF2b, the first part RF3-1 of the third reflection plate RF3, and first part RF4-1 of the fourth reflection plate RF4 which are electrically connected to the light emitting diode 130 at the outside of the light emitting diode 130.

The example embodiments of the present disclosure can also be described as follows:

According to an aspect of the present disclosure, there is provided a display device. The display device comprises a substrate including an active area in which a plurality of sub pixels are disposed and a non-active area enclosing the active area. The display device further comprises a plurality of light emitting diodes which are disposed in each of the plurality of sub pixels and includes a first electrode and a second electrode. The display device further comprises a plurality of transistors disposed in each of the plurality of sub pixels. The display device further comprises a plurality of reflection plates which are disposed below the plurality of light emitting diodes in the plurality of sub pixels. The display device further comprises an insulating layer disposed on the plurality of reflection plates. The plurality of reflection plates include a first part overlapping a contact hole of the insulating layer and a second part extending from the first part, and the first part and the second part are formed of different materials from each other.

A reflectance of the second part can be higher than a reflectance of the first part.

The second part can include a plurality of layers, and the first part includes some of the plurality of layers.

The second part can include a first layer, a second layer disposed on the first layer, a third layer disposed on the second layer, and a fourth layer disposed on the third layer and the first part includes the first layer.

The plurality of sub pixels can include a first sub pixel, a second sub pixel, a third sub pixel, and a fourth sub pixel. The plurality of reflection plates can include a first reflection plate disposed in the first sub pixel, a second reflection plate disposed in the second sub pixel, a third reflection plate disposed in the third sub pixel, and a fourth reflection plate disposed in the fourth sub pixel. The first reflection plate can include a 1-2-th reflection plate overlapping a light emitting diode disposed in the first sub pixel and a 1-1-th reflection plate spaced apart from the 1-2-th reflection plate. The second reflection plate can include a 2-2-th reflection plate overlapping a light emitting diode disposed in the second sub pixel and a 2-1-th reflection plate spaced apart from the 2-2-th reflection plate. The insulating layer can include an adhesive layer disposed between the reflection plate and the plurality of light emitting diodes and a planarization layer which covers at least a part of the plurality of light emitting diodes.

The display device can further comprise a plurality of first connection electrodes which electrically connect a high potential power line and the second electrodes of the plurality of light emitting diodes. The display device can further comprise a plurality of second connection electrodes which electrically connect the plurality of transistors and the first electrodes of the plurality of light emitting diodes. The plurality of first connection electrodes and the plurality of second connection electrodes can be in contact with the reflection plate through a contact hole of the insulating layer.

The 1-1-th reflection plate and the 2-1-th reflection plate can be connected to the plurality of transistors. The 1-2th reflection plate and the 2-2th reflection plate can be connected to the high potential power line, The third reflection plate and the fourth reflection plate can be connected to the plurality of transistors.

The first part among the first part and the second part can be in contact with the plurality of first connection electrodes and the plurality of second connection electrodes.

Each of the plurality of first connection electrodes can electrically connect a second electrode of the light emitting diode disposed in the first sub pixel and the 1-2-th reflection plate and electrically connect a second electrode of the light emitting diode disposed in the second sub pixel and the 2-2-th reflection plate.

Each of the plurality of second connection electrodes can electrically connect a first electrode of the light emitting diode disposed in the first sub pixel and the 1-1-th reflection plate. Each of the plurality of second connection electrodes can electrically connect a first electrode of the light emitting diode disposed in the second sub pixel and the 2-1-th reflection plate. Each of the plurality of second connection electrodes can electrically connect a first electrode of a light emitting diode disposed in the third sub pixel and the third reflection plate. Each of the plurality of second connection electrodes can electrically connect a first electrode of a light emitting diode disposed in the fourth sub pixel and the fourth reflection plate.

The light emitting diode disposed in the first sub pixel and the light emitting diode disposed in the second sub pixel can be red light emitting diodes. A light emitting diode disposed in the third sub pixel can be a green light emitting diode. A light emitting diode disposed in the fourth sub pixel can be a blue light emitting diode.

The second layer and the third layer can be formed of a material having a reflectance higher than those of the first layer and the fourth layer.

The second layer and the third layer can be formed of a metal material and the first layer and the fourth layer can be formed of transparent conductive oxide.

A reflectance of the third layer can be higher than a reflectance of the second layer.

The first layer and the fourth layer can be formed of ITO, the second layer can be formed of molybdenum (Mo), and the third layer can be formed of aluminum (Al).

The second layer, the third layer, and the fourth layer can have the same area on the plane.

The display device can further comprise a plurality of pad electrodes which are disposed in the non-active area and is connected to the plurality of sub pixels. The plurality of pad electrodes can include a conductive layer formed of the same material as the first part.

The active area can further include a plurality of gate driving areas which extend from the plurality of sub pixels and includes a gate driver disposed therein.

Active layers of the plurality of transistors disposed in the plurality of sub pixels and active layers of the plurality of transistors disposed in the gate driver can be formed by oxide semiconductor, amorphous silicon, or polysilicon.

The plurality of transistors disposed in the gate driver can include active layers formed of different materials.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area and a non-active area adjacent to the active area, the active area including a plurality of sub pixels of at least one pixel disposed thereon;
a plurality of light emitting diodes disposed in the plurality of sub pixels, respectively, and including a first electrode and a second electrode, respectively;
a plurality of transistors disposed in the plurality of sub pixels, respectively;
a plurality of reflection plates disposed below the plurality of light emitting diodes in the plurality of sub pixels, respectively; and
an insulating layer disposed on the plurality of reflection plates,
wherein the plurality of reflection plates respectively include a first part overlapping a contact hole of the insulating layer and a second part extending from the first part, and the first part and the second part include different materials from each other.

2. The display device according to claim 1, wherein a reflectance of the second part is higher than a reflectance of the first part.

3. The display device according to claim 1, wherein the second part includes a plurality of layers, and the first part includes some of the plurality of layers.

4. The display device according to claim 3, wherein the second part includes a first layer, a second layer disposed on the first layer, a third layer disposed on the second layer, and a fourth layer disposed on the third layer, and the first part includes the first layer.

5. The display device according to claim 4, wherein the plurality of sub pixels include a first sub pixel, a second sub pixel, a third sub pixel, and a fourth sub pixel,
wherein the plurality of reflection plates include a first reflection plate disposed in the first sub pixel, a second reflection plate disposed in the second sub pixel, a third reflection plate disposed in the third sub pixel, and a fourth reflection plate disposed in the fourth sub pixel,
wherein the first reflection plate includes a 1-2-th reflection plate overlapping a first light emitting diode of the plurality of light emitting diodes disposed in the first sub pixel and a 1-1-th reflection plate spaced apart from the 1-2-th reflection plate,
wherein the second reflection plate includes a 2-2-th reflection plate overlapping a second light emitting diode of the plurality of light emitting diodes disposed in the second sub pixel and a 2-1-th reflection plate spaced apart from the 2-2-th reflection plate, and
wherein the insulating layer includes an adhesive layer disposed between the reflection plate and the plurality of light emitting diodes and a planarization layer which covers at least a part of the plurality of light emitting diodes.

6. The display device according to claim 5, further comprising:
a plurality of first connection electrodes which electrically connect a high potential power line and second electrodes of the plurality of light emitting diodes, respectively; and
a plurality of second connection electrodes which electrically connect the plurality of transistors and first electrodes of the plurality of light emitting diodes, respectively,
wherein the plurality of first connection electrodes and the plurality of second connection electrodes are in contact with the plurality of reflection plates, respectively, through the contact hole of the insulating layer.

7. The display device according to claim 6, wherein the 1-1-th reflection plate and the 2-1-th reflection plate are connected to the plurality of transistors, respectively, the 1-2th reflection plate and the 2-2th reflection plate are connected to the high potential power line, and the third reflection plate and the fourth reflection plate are connected to the plurality of transistors, respectively.

8. The display device according to claim 6, wherein the first part among the first part and the second part is in respective contact with the plurality of first connection electrodes and the plurality of second connection electrodes.

9. The display device according to claim 6, wherein each of the plurality of first connection electrodes electrically connects the second electrode of the first light emitting diode disposed in the first sub pixel and the 1-2-th reflection plate and electrically connects the second electrode of the second light emitting diode disposed in the second sub pixel and the 2-2-th reflection plate.

10. The display device according to claim 6, wherein each of the plurality of second connection electrodes electrically connects the first electrode of the first light emitting diode disposed in the first sub pixel and the 1-1-th reflection plate, electrically connects the first electrode of the second light emitting diode disposed in the second sub pixel and the 2-1-th reflection plate, electrically connects the first electrode of a third light emitting diode of the plurality of light emitting diodes disposed in the third sub pixel and the third reflection plate, and electrically connects the first electrode of a fourth light emitting diode of the plurality of light emitting diodes disposed in the fourth sub pixel and the fourth reflection plate.

11. The display device according to claim 6, wherein the first light emitting diode disposed in the first sub pixel and the second light emitting diode disposed in the second sub pixel are red light emitting diodes,
wherein a third light emitting diode disposed in the third sub pixel of the plurality of light emitting diodes is a green light emitting diode, and
wherein, a fourth light emitting diode disposed in the fourth sub pixel of the plurality of light emitting diodes is a blue light emitting diode.

12. The display device according to claim 4, wherein the second layer and the third layer include a material having a reflectance higher than those of the first layer and the fourth layer.

13. The display device according to claim 12, wherein the second layer and the third layer include a metal material, and the first layer and the fourth layer include a transparent conductive oxide.

14. The display device according to claim 12, wherein the reflectance of the third layer is higher than the reflectance of the second layer.

15. The display device according to claim 4, wherein the first layer and the fourth layer include indium tin oxide (ITO), the second layer includes molybdenum (Mo), and the third layer includes aluminum (Al).

16. The display device according to claim 4, wherein the second layer, the third layer, and the fourth layer have a same area on a plane view.

17. The display device according to claim 1, further comprising:
a plurality of pad electrodes disposed in the non-active area and connected to the plurality of sub pixels, respectively,
wherein the plurality of pad electrodes include a conductive layer formed of a same material as the first part.

18. The display device according to claim 1, wherein the active area further includes a plurality of gate driving areas which extend from the plurality of sub pixels and include a gate driver respectively disposed therein.

19. The display device according to claim 18, wherein active layers of the plurality of transistors disposed in the plurality of sub pixels and active layers of the plurality of transistors disposed in the plurality of gate driving areas are formed by an oxide semiconductor, amorphous silicon, or polysilicon.

20. A display device, comprising:
at least one pixel including a plurality of sub pixels;
a plurality of light emitting diodes disposed at the plurality of sub pixels, respectively, and each light emitting diode including a first electrode and a second electrode;
a plurality of transistors disposed at the plurality of sub pixels, respectively;
a plurality of reflection plates disposed between the plurality of light emitting diodes and the plurality of transistors in the plurality of sub pixels, respectively; and
an insulating layer disposed between the plurality of light emitting diodes and the plurality of reflection plates,
wherein, in a sub pixel of the plurality of sub pixels, a reflection plate of the plurality of reflection plates is electrically connected to one of the first electrode and the second electrode of a light emitting diode of the plurality of light emitting diodes so that a voltage applied to the reflection plate and to one of the first electrode and the second electrode is the same.
